(19) United States
(12) Patent Application Publication
(10) Pub. No.: US 2013/0210982 A1
(43) Pub. Date: Aug. 15, 2013

(54) SILICONE RESIN COMPOSITION HAVING HIGH REFRACTIVE INDEX

(71) Applicants: Pei Tien, Yangmei (TW); Hsu-Hsiu Lee, Taipei (TW); Pei Chun Chang, Taoyuan (TW)

(72) Inventors: Pei Tien, Yangmei (TW); Hsu-Hsiu Lee, Taipei (TW); Pei Chun Chang, Taoyuan (TW)

(73) Assignee: 3M INNOVATIVE PROPERTIES COMPANY, St. Paul, MN (US)

(21) Appl. No.: 13/877,681

(22) PCT Filed: Oct. 14, 2011
(86) PCT No.: PCT/US11/56312

§ 371 Date: Apr. 4, 2013

(30) Foreign Application Priority Data
Oct. 27, 2010 (CN) 201010525520.6

(51) Int. Cl. C09D 183/00; H01L 33/54

(52) U.S. Cl. CPC C09D 183/00; H01L 33/54
USPC 524/264; 438/26

(57) ABSTRACT

The present disclosure relates to a silicone resin composition comprising a silicone resin having at least one terminal hydrogen group, a metal alkoxide having at least one C₁₋₆ ailcoxy group, and a silane having at least one terminal vinyl group and at least one terminal C₁₋₆ alkoxy or hydroxyl group. The composition cured has a refractive index greater than 1.4. The present disclosure also relates to an optoelectronic device, which is encapsulated with the aforementioned composition.

### TECHNICAL FIELD

The present disclosure relates to a silicone resin composition and an optoelectronic device encapsulated with a cured product of the composition.

### BACKGROUND

Silicone resins are often used in optoelectronic devices because silicone resins have excellent optical properties, such as high thermal stability, weatherability, photostability, and flexibility, not to mention that silicone resins are more reliable than epoxy resins. However, the refractive index of silicone resins is about 1.4; as a result, when silicone resins are used as an encapsulant for optoelectronic devices, such as light-emitting diodes (LEDs), the low refractive index will lead to a low extraction efficiency and thereby reduce LED brightness.

Related prior art teaches producing a material of high refractive index by organic synthesis technology. For example, JP 63-077872 discloses a method for increasing the refractive index of a material by increasing the bromine to iodine atomic ratio in its main structure; however, not only is the refractive index increase achieved by this method rather limited, but the application of the aforesaid halogen-containing material is gradually restricted due to increasingly high green awareness.

Taiwan Patent Publication No. 200609299 provides a silicone resin composition for use as an LED encapsulant and discloses a method for obtaining a silicone resin composition of high refractive index by increasing its content of aromatic groups. However, the method will reduce the stability of the composition, and the composition is prone to yellowing at high temperatures.

### SUMMARY

The inventor of this invention discovers that the silicone resin composition of the present invention has a high refractive index while keeping the advantages of silicone resins.

In one aspect, the present disclosure provides a silicone resin composition comprising:
(a) a silicone resin having at least one terminal hydrogen group;
(b) a metal alkoxide having at least one C₁₋₆ alkoxy group; and
(c) a silane having at least one terminal vinyl group and at least one terminal C₁₋₆ alkoxy or hydroxyl group.

In another aspect, the present disclosure provides a method for encapsulating an optoelectronic device, the method comprising the steps of:
(a) providing an optoelectronic device; and
(b) encapsulating the optoelectronic device with the aforesaid silicone resin composition.

Yet another aspect of the present disclosure is to provide a light-emitting semiconductor device.

A further aspect of the present disclosure is to provide a method for adjusting the refractive index of a silicone resin.

### BRIEF DESCRIPTION OF THE DRAWINGS

FIG. 1 is a cross-sectional view of an LED device comprising a cured silicone resin produced from the composition of the present disclosure; and

FIG. 2 shows an infrared spectrum of the products of reaction between a metal alkoxide and a vinylsilane.

### DETAILED DESCRIPTION OF THE INVENTION

The present invention relates to a silicone resin composition comprising:
(a) a silicone resin having at least one terminal hydrogen group;
(b) a metal alkoxide having at least one C₁₋₆ alkoxy group; and
(c) a silane having at least one terminal vinyl group and at least one terminal C₁₋₆ alkoxy or hydroxyl group.

To render the features and advantages of the present disclosure salient and comprehensible, the present disclosure is hereunder illustrated with preferred embodiments and drawings.

### Silicone Resin

Constituent (a) of the composition of the present disclosure is a silicone resin having at least one terminal hydrogen group. The silicone resin comprises a compound with a structure expressed as follows:

(HR¹SiO)ₓ−(R²R³SiO)_{y}
wherein R¹, R², and R³ may be identical or different C₁₋₆ alkyl groups, or preferably C₁₋₄ alkyl groups; x and y denote polymerization number, and x is at least 1.

The silicone resin is selected according to required properties (such as heat resistance, durability, and mechanical strength). The silicone resin thus selected comes in the form of a single silicone or a combination of two or more polydisiloxanes of different viscosity, structure, average molecular weight, silicon-oxygen unit, and sequence.

There are no special restrictions upon the molecular weight of the silicone resin of the present disclosure. The average molecular weight of the silicone resin of the present disclosure preferably ranges between 500 and 200,000, or more preferably ranges between 700 and 60,000. The silicone resin content of the composition of the present disclosure is about 20% to 60% by weight, or preferably about 30% to 40% by weight based on the total weight of the composition.

### Metal Alkoxide

Constituent (b) of the composition of the present disclosure is a metal alkoxide with a structure expressed as follows:

Rₘ−M(OR′)ₙ

wherein R and R′ may be identical or different C₁₋₆ alkyl groups, or preferably C₁₋₄ alkyl groups. M denotes a semiconductor or metal having a vacant orbital, preferably titanium (Ti), zirconium (Zr), aluminum (Al), niobium (Nb), indium (In), cerium (Ce), hafnium (Hf), tantalum (Ta), silicon (Si) or germanium (Ge), or more preferably titanium, zirconium, or aluminum; m denotes an integer that ranges between 0 and 3, and n denotes an integer that ranges between 1 and 4, wherein 1≦m+n≦4.

Preferably, the metal alkoxide includes Zr(OBu)₄, Ti(OBu)₄, or a mixture thereof.

The metal alkoxide content of the composition of the present disclosure is about 30% to 70% by weight, or preferably about 50% to 60% by weight based on the total weight of the composition.

### Silane

Constituent (c) of the composition of the present disclosure is a silane having at least one terminal vinyl group and at least one terminal C₁₋₆ alkoxy or hydroxyl group. The silane applicable to the composition of the present disclosure includes, but is not limited to, vinyltrimethoxysilane, vinyltriethoxysilane, vinyltri(2-methoxyethoxy)silane, vinylmethyldimethoxysilane, vinylmethyldiethoxysilane, vinylphenyldimethoxysilane, and a mixture thereof.

The silane resin content of the composition of the present disclosure is about 1% to 10% by weight based on the total weight of the composition.

### Encapsulation of Optoelectronic Device

The composition of the present disclosure is applicable to encapsulation of optoelectronic devices, such as a light-emitting semiconductor device. The light-emitting semiconductor device can be a light-emitting diode (LED). Encapsulation technology applicable to the optoelectronic devices is well known in the art. For example, after an optoelectronic device has been encapsulated in an uncured silicone resin composition, a curing process is usually performed on the composition inside a mold. The composition can be cured by being heated up in one or more stages. For example, the curing process can take place at temperatures that range between room temperature and 200° C.

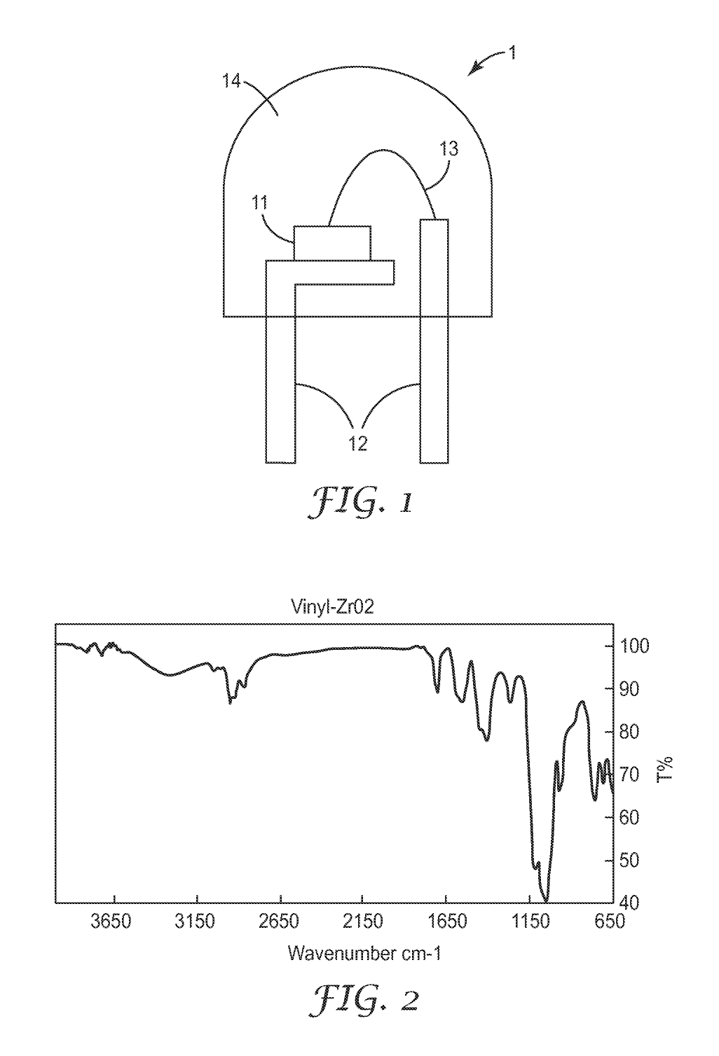

FIG. 1 is a cross-sectional view of an LED device 1 having a cured silicone resin produced from the composition of the present disclosure. The LED device 1 comprises an LED chip 11. The LED chip 11 may be directly electrically connected to an anode or cathode of a leadframe 12 and connected to another cathode or anode of the leadframe 12 via a wire 13. The LED chip 11 may be a p-n junction LED chip comprising any semiconductor layer capable of emitting required light. For example, the LED chip 11 may comprise any required semiconductor layer of Group MN compounds, such as gallium arsenide, aluminum gallium nitride, indium gallium nitride, or gallium phosphide, or any required semiconductor layer of Group II-IV compounds, such as zinc selenide, cadmium telluride, or zinc sulfoselenide, or any required semiconductor layer of Group IV-IV compounds, such as silicon carbide. The LED chip 11 is encapsulated with an encapsulant 14 produced from the silicone resin composition of the present disclosure.

The present disclosure is further described with the following embodiments, which are provided for illustration of the present disclosure only, and in no way limit the scope of the present disclosure. Hence, modifications and changes that may be easily made by those skilled in the art are within the scope of the disclosure contained in the specification of the present disclosure and the appended claims.

### EXAMPLES

### Synthesis of Silicone Resin Composition

### Example 1

14 g of vinyltrimethoxysilane, 5 g of diphenyldimethoxysilane, 30 g of toluene, 10 g of ethanol, and several drops of acetic acid were added into a 3-neck flask and mixed. The mixture was stirred at room temperature for 30 minutes before 12.5 g of Zr(OBu)₄ was added, and then distilled by reverse distillation at 80° C. for three hours. Upon completion of the reverse distillation, the top layer solution was added into a rotary evaporator (Büchi) to remove solvent at 70° C. Afterwards, 19 g of slightly yellowish but extremely clear liquid was obtained. Infrared (IR) spectrum analysis was performed on the liquid obtained, and its result is shown in FIG, 2.

### Example 2

10 g of Ti(OBu)₄, 30 g of toluene, 4.5 g of ethanol, several drops of acetic acid, and 5 g of vinyltrimethoxysilane were stirred at room temperature for 30 minutes. Then, the mixture and 15 g of trimethylmethoxysilane were added into a 3-neck flask and mixed, and then distilled by reverse distillation at 80° C. for three hours. Upon completion of the reverse distillation, the top layer solution was added into a rotary evaporator (Büchi) to remove solvent at 70° C. Afterwards, 16 g of slightly yellowish but extremely clear liquid was obtained.

### Example 3

0.6 g of the solution obtained in Example 2, 1.55 g of X-101 (silicone resin, ADSET MATERIALS COMPANY), and 2% platinum were stirred at room temperature for 30 minutes.

### Comparative Example 1

1366A and 1366B (silicone resin, ADSET MATERIALS COMPANY), 0.5 g each, were stirred at room temperature for 30 minutes.

### Testing Refractive Index of the Silicone Resin Composition

A certain amount of the solutions obtained in Example 3 and Comparative Example 1, respectively, was diluted with toluene until the diluted solutions have a concentration by weight equivalent to 50% of the original concentration. Afterwards, several drops of the diluted solutions were added onto a chip, which was placed in a spin coater with its rotation speed set to 500 RPM, and was run for 30 seconds, and then baked at 150° C. for 30 minutes. Finally, the refractive index of the baked material was measured at 632.8 nm with a prism coupler (Metricon Model 2010), and the result is shown in Table 1.

TABLE 1

| Example | Refractive Index |
|---|---|
| Example 3 | 1.4561 |
| Comparative Example 1 | 1.4047 |

Various modifications and changes to the present disclosure should be obvious to those skilled in the art, provided that they do not depart from the scope and principles of the present disclosure. Persons skilled in the art should understand that the present disclosure is not unduly limited to the aforesaid illustrative embodiments. All published patent applications and granted patents are incorporated in this specification by reference in the same way as each published patent application or granted patent is incorporated in this specification by reference as specifically and individually indicated.

1. A silicone resin composition, comprising:
(a) a silicone resin having at least one terminal hydrogen group;
(b) a metal alkoxide having at least one C₁₋₆ alkoxy group; and
(c) a silane having at least one terminal vinyl group and at least one terminal C₁₋₆ alkoxy or hydroxyl group.

2. The composition of claim 1, comprising about 20% to 60% by weight of silicone resin.

3. The composition of claim 1, comprising about 30% to 70% by weight of metal alkoxide.

4. The composition of claim 1, comprising about 1% to 10% by weight of silane.

5. The composition of claim 1, wherein the composition has a refractive index greater than 1.4 when cured.

6. The composition of claim 1, wherein the metal alkoxide has a structure expressed as follows:
Rₘ−M(OR′)ₙ,
wherein M denotes a semiconductor or metal having a vacant orbital, wherein R and R′ may independently be identical or different C₁₋₆ alkyl groups, m denotes an integer ranging between 0 and 3, and n denotes an integer ranging between 1 and 4, wherein 1≦m+n≦4.

7. The composition of claim 6, wherein M is selected from the group consisting of titanium, zirconium, aluminum, niobium, indium, cerium, hafnium, tantalum, silicon, and germanium.

8. The composition of claim 6, wherein R and R′ may independently be identical or different C₁₋₄ alkyl groups.

9. The composition of claim 6, wherein m is 0 and n is 4.

10. The composition of claim 1, wherein the metal alkoxide is Zr(OBu)₄ or Ti(OB)₄.

11. The composition of claim 1, wherein the silane is selected from the group consisting of vinyltrimethoxysilane, vinyltriethoxysilane, vinyltri(2-methoxyethoxy)silane, vinylmethylditnethoxysilane, vinytmethyldiethoxysilane, vinylphenylditnethoxysilane, and a mixture thereof.

12. A method for encapsulating an optoelectronic device, the method comprising the steps of:
(a) providing an optoelectronic device; and
(b) encapsulating the optoelectronic device with the silicone resin composition of claim 1.

13. The method of claim 12, further comprising the step of curing the silicone resin composition.

14. A light-emitting semiconductor device comprising a component encapsulated with a cured product of the composition of claim 1.

15. A method for adjusting refractive index of a silicone resin, the method comprising adding a metal alkoxide having at least one C₁₋₆ alkoxy group and a silane having at least one terminal vinyl group and at least one terminal C₁₋₆ alkoxy or hydroxyl group to a silicone resin having at least one terminal thiol group.

16. The method of claim 15, wherein the refractive index is greater than 1.4.
